(19) United States
(12) Patent Application Publication
(10) Pub. No.: US 2008/0227241 A1
(43) Pub. Date: Sep. 18, 2008

(54) METHOD OF FABRICATING SEMICONDUCTOR DEVICE

(76) Inventors: Yukio Nakabayashi, Kanagawa (JP); Junji Koga, Kanagawa (JP); Atsuhiro Kinoshita, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/043,327

(22) Filed: Mar. 6, 2008

(30) Foreign Application Priority Data
Mar. 12, 2007 (JP) 2007-061164

(51) Int. Cl. H01L 21/84

(52) U.S. Cl. 438/150; 257/E21.7

(57) ABSTRACT

A semiconductor device fabrication method for forming on a wafer-bonded substrate p- and n-type FinFETs each having a channel plane exhibiting high carrier mobility is disclosed. First, prepare two semiconductor wafers. Each wafer has a surface of {100} crystalline orientation and a <110> direction. These wafers are surface-bonded together so that the <110>directions of upper and lower wafers cross each other at a rotation angle, thereby providing a “hybrid” crystal-oriented substrate. On this substrate, form semiconductor regions, one of which is identical in <110> direction to the upper wafer, and the other of which is equal in <110> direction to the lower wafer. In the one region, form a pFinFET having {100} channel plane. In the other region, form an nFinFET having its channel direction in parallel or perpendicular to that of the pFinFET. A CMOS FinFET structure is thus obtained.

### CROSS-REFERENCE TO RELATED APPLICATION

This application is based upon and claims the benefit of priority from Japanese Patent Application No. 2007-61164, filed Mar. 12, 2007, the entire contents of which is incorporated herein by reference.

### FIELD OF THE INVENTION

The present invention relates generally to a method of fabricating semiconductor device with field effect transistors (FETs) and, more particularly, to a method of fabricating semiconductor device with transistors of the type having a channel structure of the fin form.

### BACKGROUND OF THE INVENTION

Ultralarge-scale integrated (ULSI) devices employ field effect transistors (FETs) as principal circuit elements thereof. For further performance enhancement of ULSI chips, it is inevitable to improve performances of these FETs. Until today, the improvement of on-chip circuit element performances has been advanced in a way relying chiefly upon miniaturization or downsizing of such elements. However, it is pointed out that in near future, this approach to attaining higher performances by the scaling reaches the limit. Usually the performance of an FET is determined by a drive current during its turn-on operations and a channel leakage current in turn-off events. If the drive current is large and the channel leakage current is less, the FET performance increases. According to the International Technology Roadmap for Semiconductors (ITRS), it is pointed out that in ULSI devices of the generation with minimum feature sizes of 45 nanometers (nm) or later generations, a need is felt to give several breakthroughs to the scaling limits in order to attain the goal of a larger drive current and less leakage current.

To achieve the reduction of the off-state channel leakage current, a transistor of the type having a fully depleted (FD) channel is expected for use as next-generation circuit elements because of its advantage as to increased immunity against short channel effects. Some examples of such FD-channel transistor include a transistor having a thin film silicon-on-insulator (SOI) substrate and a field effect transistor (FET) having a fin shaped channel, called the fin FET or “FinFET.” This FinFET is a one type of multi-gate transistor which has a channel of vertical or “standing” fin form on or above a substrate thereof.

Known approaches that are proposed as the solution to increasing the drive current during turn-on operations include the so-called “strained channel” technology and semiconductor substrate crystalline orientation engineering. The latter refers to an ensemble of techniques for optimizing, from a viewpoint of carrier mobility, the crystal plane of a channel region of n-type transistor with electrons as its majority carriers and the crystal plane of a channel of p-type transistor with holes as its carriers. Presently the most popular semiconductor material for use as substrate material of ULSI devices must be silicon, which is different in crystalline orientation exhibiting high mobility between for electrons and for holes. Specifically, as far as electrons are concerned, the carrier mobility of Si is the highest in a <110> direction on a (110) plane; for holes, the mobility of Si becomes maximal in the <110> direction on a (100) plane.

Regarding the semiconductor substrate crystal orientation engineering, there is known a technique for using a semiconductor substrate with bonded Si wafers having different crystal orientations to form planar transistors thereon. This technique is disclosed, for example, in M. Yang et al., “High Performance CMOS Fabricated on Hybrid Substrate With Different Crystal Orientations,” International Electron Devices Meeting (IEDM) Technical Digest, pp. 453-456 (2003).

As previously stated, for suppression of short channel effects, it is a promising way to employ the FinFET structure. Additional advantage of FinFET lies in its ability to select the optimum crystal plane of a vertically standing channel region by adequately determining the patterning direction of such channel region in the case of the crystal orientation engineering being carried out.

Traditionally, in the manufacture of ULSI devices using FinFETs on a Si(100) plane, it is required in view of its crystalline structure to rotate the channel patterning direction for pFinFETs relative to that for nFinFETs by about an angle of 45 degrees in order to obtain a large drive current. In other words, for setting the channel plane of nFET to a {100} plane while setting the channel plane of pFET to a {110} plane, it is not permissible to perform layout design so that respective channel directions are either in parallel with or normal to each other. This layout limit places significant restrictions or constraints on the design of complementary metal oxide semiconductor (CMOS) circuitry having both nFETs and pFETs on the same substrate. The presence of such design constraints is a serious bar to the quest for higher integration of ULSIs.

There is thus a need to provide a semiconductor device fabrication method capable of forming on a semiconductor wafer-bonded substrate p- and n-type FinFETs each having a channel plane high in carrier mobility.

### SUMMARY OF THE INVENTION

In accordance with one aspect of this invention, a semiconductor device fabrication method is provided, which includes preparing a semiconductor substrate with a bonded structure of first and second semiconductor wafers each having a surface of {100} crystal orientation. These wafers are in contact with each other so that a <110> direction of the first wafer is not identical to that of the second wafer. Then, form on a surface of the substrate a first semiconductor region with its <110> direction being identical to the <110> direction of the first wafer and a second semiconductor region with its <110> direction identical to the <110> direction of the second wafer. Next, form in the first region a p-conductivity type fin field effect transistor (pFinFET) so that its channel plane becomes a {110} plane. In the second region, form an n-type fin field effect transistor (nFinFET) so that its channel direction is either in parallel with or perpendicular to the channel direction of the pFinFET.

In accordance with another aspect of the invention, a semiconductor device fabrication method includes preparing a semiconductor substrate with a bonded structure of first and second semiconductor wafers each having a surface of {100} crystal orientation. These wafers are in contact with each other so that a <110> direction of the first wafer is not identical to that of the second wafer. Then, form on a surface of the substrate a first semiconductor region with its <110> direction being identical to the <110> direction of the first wafer and a second semiconductor region with its <110> direction identical to the <110> direction of the second wafer. Next, form in the second region an nFinFET so that its channel plane becomes the {100} plane. In the first region, form a pFinFET so that its channel direction is either in parallel with or perpendicular to the channel direction of the nFinFET.

### BRIEF DESCRIPTION OF THE DRAWINGS

FIG. 1 is a diagram depicting in cross-section a CMOS device structure having a pair of p- and n-type FinFETs in accordance with one embodiment of this invention.

FIGS. 2A to 2C are explanation diagrams of a procedure for preparation of an SOI substrate of the CMOS device.

FIGS. 3 through 21 illustrate, in cross-section or in plan view diagram forms, some major steps in the manufacture of the CMOS device.

FIG. 22 is a cross-sectional view of a CMOS device with a pair of pFinFET and nFinFET in accordance with another embodiment of the invention.

FIGS. 23A to 23C are explanation diagrams of a procedure of preparing an SOI substrate of CMOS device in accordance with still another embodiment of the invention.

FIG. 24 illustrates, in cross-section, a fin-type CMOS device formed on the SOI substrate of FIGS. 23A-23C.

FIGS. 25A-25C are explanation diagrams of a procedure of preparing an SOI substrate of fin-type CMOS device in accordance with yet another embodiment of the invention.

FIG. 26 shows in cross-section a fin-type CMOS device formed on the SOI substrate of FIGS. 25A-25C.

FIGS. 27 to 29 are diagrams each showing a sectional view of a fin-type CMOS device in accordance with a further embodiment of the invention.

FIGS. 30 and 31 are diagrams each showing a p-channel FinFET in accordance with another further embodiment of the invention.

### DETAILED DESCRIPTION OF THE EMBODIMENTS

In currently preferred embodiments as disclosed herein, semiconductor substrates therefor exemplify the use of silicon (Si) wafers. It should be appreciated that the Si wafers are illustrative only and are not to be construed as limiting the invention.

In the description below, a full set of planes which is crystallographically equivalent to a (hkl) plane will be represented by {hkl}. For example, {100} for (100), and {110} for (110). Additionally, a set of equivalent directions to a [uvw] direction is denoted by <uvw>; for example, <100> for [100], and <110> for [110].

The term “channel plane” as will be used in the description refers to the interface between a channel region and gate insulator film of a fin-type field effect transistor (FinFET). The term “channel direction” will be used to mean the direction of a flow of charge carriers in FinFET. The carriers may be electrons or holes.

In case the description contains a recitation saying that a semiconductor wafer has a specific crystal plane, this plane should be interpreted to indicate not only a plane that is completely identical thereto but also planes that have certain oblique or tilt angles—e.g., plus/minus (±) 2 degrees—relative to the specific crystal plane. The same goes with the wafer's crystal direction and FinFET's channel plane. For example, regarding the former, in case the description involves a recitation saying that a semiconductor region's crystal orientation is identical to a <110> direction of Si wafer, some other directions having angular deviations of about ±2 degrees relative to such direction are also included therein. As for the FinFET channel plane, when the description says that the channel plane is identical to a {110} plane, other approximate planes having angular deviations of about ±2 degrees relative to the {110} plane may also be included therein. Even with the inclusion of such “allowable” angle error range, advantages unique to the invention are still attainable.

A semiconductor wafer having its top surface on a (100) crystal plane is of crystallographic four-fold symmetry in a <100> crystal axis direction normal to the (100) plane. Accordingly, in the indication of angles in this description, an angle θ and its related specific angles, such as θ+n×90 degrees (where n is 0, 1, 2, 3), are all regarded to be the equivalent angle in the sense of crystallography. For instance, if θ is 45 degrees then four angles of 45, 135, 225 and 315 degrees are assumed to be the same angle.

### Embodiment 1

A semiconductor device fabrication method incorporating the principles of the invention starts with preparation of a silicon-on-insulator (SOI) substrate. This SOI substrate is comprised of two separate round disc-like silicon (Si) wafers. A “first” Si wafer has a surface on a (100) crystal plane. A “second” Si wafer has also its surface on the (100) plane. These wafers are surface-bonded together while letting them relatively rotate about the mated disc center to have a predetermined angle of about 45±2 degrees between a <100> direction of the first wafer and the <100> direction of the second wafer. Then, on a top surface of the resulting bonded SOI substrate, form laterally neighboring semiconductor regions. One of these semiconductor regions has its <110> direction identical to a <110> direction of the upper wafer whereas the other region has its <110> direction equal to the <110> direction of the lower wafer. Next, form in one region a p-channel fin field effect transistor (pFinFET) with its channel plane on a {110} plane. Also form in the other region an n-channel fin FET (nFinFET) with its channel direction being either in parallel with or perpendicular to the channel direction of pFinFET—that is, the nFinFET has a channel plane identical to a {100} plane.

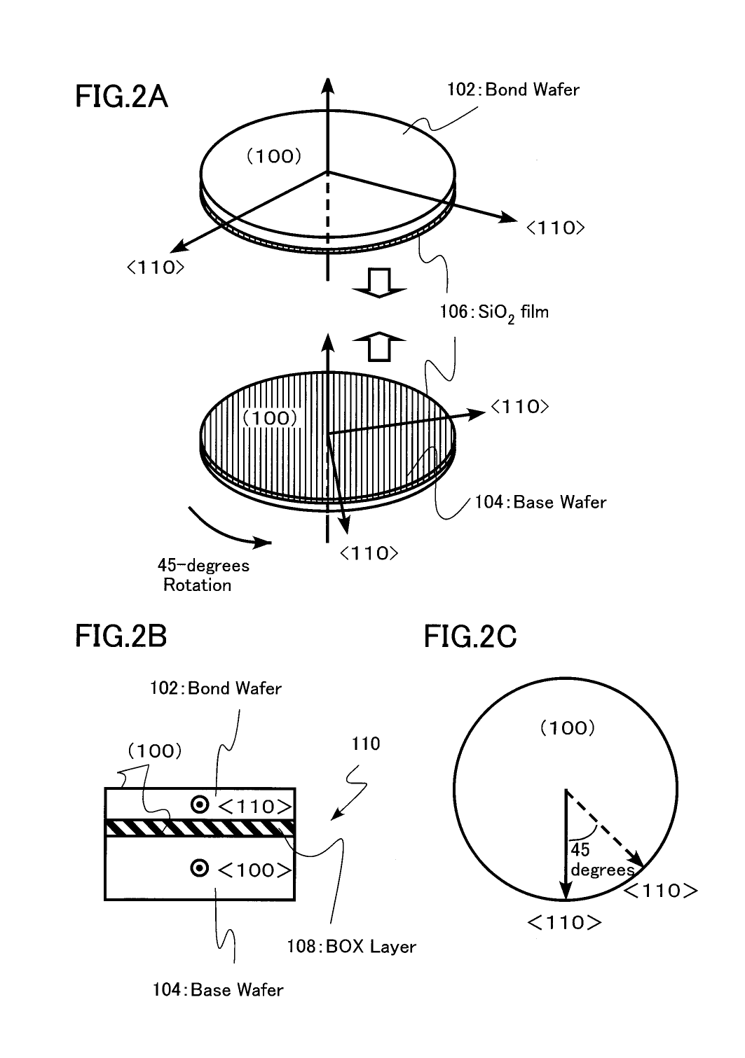

More specifically, to fabricate the bonded SOI substrate, what is done first is to prepare two separate Si wafers 102 and 104, which are different in crystal orientation from each other as shown in FIG. 2A. The upper wafer 102 has its top surface on a (100) crystal plane. The lower wafer 104 has also its surface on the (100) plane. Apply oxidation to a back surface of the upper wafer 102 to thereby form thereon a film of silicon oxide (SiOₓ, where the suffix “x” is a positive number less than or equal to 2, typically x=2) to a thickness of about 50 nanometers (nm), as an example. This wafer 102 is for later use as the so-called bond wafer having its top surface on which semiconductor integrated circuit elements will be finally formed.

Similarly, oxidize the lower Si wafer 104's top surface having the (100) plane, thereby forming thereon a SiOₓ film to a thickness of approximately 50 nm. This wafer 104 becomes a substrate which supports the bond wafer. This supporting substrate will be referred to as base wafer hereinafter.

Next, as shown in FIG. 2A, bring the upper bond wafer 102 and lower base wafer 104 into contact with each other while causing surfaces of their SiOₓ films 106 to oppose each other in a clean atmosphere at room temperature; then, bond these wafers together. Very importantly, this wafer bonding is performed by forcing wafers 102 and 104 to relatively rotate so that the <110> direction of bond wafer 102 forms an angle of substantially 45 degrees with the <110> direction of base wafer 104. At this time, the presence of angular deviations or “errors” of about ±2 degrees (that is, an angle setup range of from about 43 degrees to about 48 degrees) may be allowable in achieving expected effects and advantages of this invention.

As shown in FIG. 2B, the resultant bonded SOI substrate 110 is such that a buried oxide (Box) layer 108 is sandwiched between the upper and lower wafers. Then, this SOI substrate is subjected to thermal treatment or “annealing” at an elevated temperature of about 800° C., for example. This annealing is for increasing the bonding strength of bonded wafer interface. Next, apply to the bond wafer 102 a chemical-mechanical polish (CMP) processing, resulting in wafer 102 being thinned to a predetermined thickness—for example, about 200 nm. This wafer thinning may be performed by known processes, such as for example SmartCut™ technique, which includes the steps of doping or implanting hydrogen ions into bond wafer 102 prior to the wafer bonding, and then performing cleaving through thermal treatment after bonding.

An upper plan view of the bonded SOI substrate 110 is shown in FIG. 2C, which is a view when looking at from the upper Si wafer 102 side, i.e., the bond wafer side. As apparent from FIG. 2C, the <110> direction of bond wafer 102 indicated by solid line arrow has an angle of 45±2 degrees relative to the <110> direction of base wafer 104, indicated by arrow of broken line. FIG. 2B depicts a cross-section in a direction of bonded SOI substrate 110 which is normal to the <110> direction of bond wafer 102: in this cross-section, the lower Si wafer, i.e., base wafer 104, has its cross-section at right angles to the <100> direction. Additionally the above-noted Box layer 107 is about 100 nm in thickness.

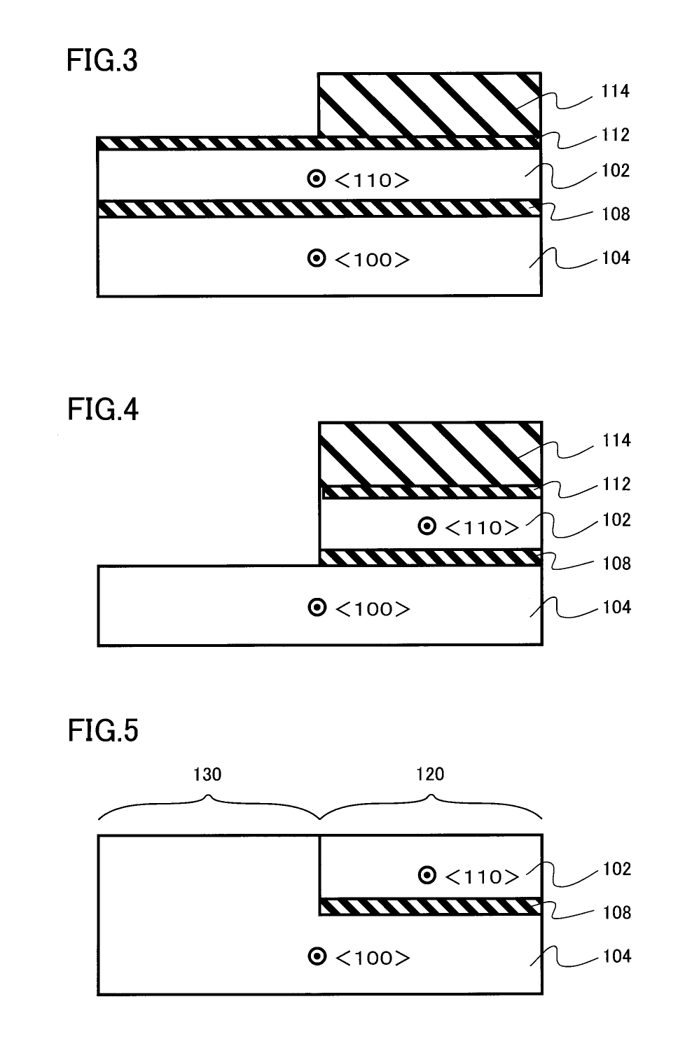

Subsequently, form on the resultant SOI substrate 110 a pair of pFinFET and nFinFET. A typical process thereof will be described with reference to FIGS. 3 to 5 below. It should be noted that in FIGS. 3-5, a circle mark with a black dot added to its center point refers to the direction normal to the surface of a drawing sheet. This direction is the <110> direction for the bond wafer (SOI layer) 102 and is the <100> for the base wafer 104.

Firstly, as shown in FIG. 3, form by thermal oxidation an SiOₓ film with a thickness of about 100 nm on the top surface of SOI substrate 110. Then, deposit a photoresist film 114 on the SiOₓ film 112 to a thickness of about 1 micrometer (μm). Then, pattern this resist film by known lithographic process to thereby cause a portion of the resist film 114 to reside only on the surface of a semiconductor region which will be used later for the formation of pFinFET.

Next as shown in FIG. 4, for the other semiconductor region in which nFinFET will be formed at a later step, selectively remove portions of the bond wafer 102's Si layer and Box layer 108 by known anisotropic etch techniques, e.g., reactive ion etching (RIE). By this selective etching, the Si surface of base wafer is partially exposed.

After having removed away the photoresist film 114, as shown in FIG. 5, use low-pressure chemical vapor deposition (LPCVD) technique at about 600° C. to force silicon to selectively grow on the exposed surface of Si base wafer 104, thus forming thereon a Si layer having its crystal direction which is the same as that of this Si wafer. After this selective growth, etch the SiOₓ film 112 that has been used as a protective film therefor. Then, planarize the SOI substrate top surface by CMP techniques.

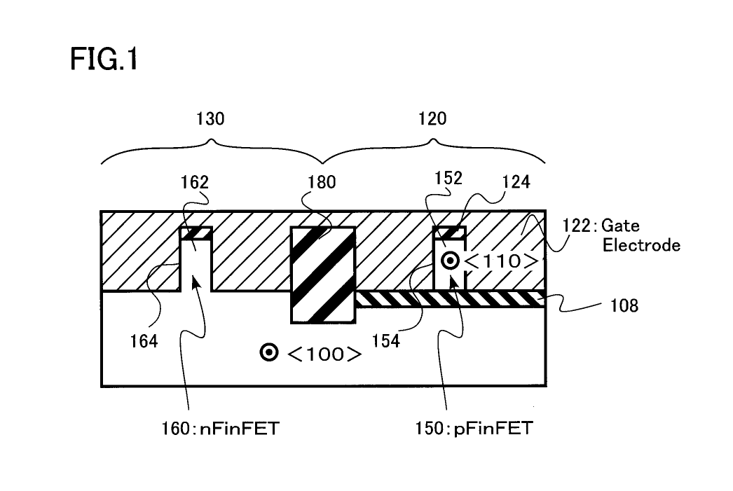

With the processes above, two laterally adjacent semiconductor regions 120 and 130 are formed in the SOI substrate as shown in FIG. 1. One region 120 has a <110> direction that is identical to the <110> direction of bond wafer 102; the other region 130 has its <110> direction identical to the <110> direction of base wafer 104. At a boundary of these semiconductor regions 120 and 130, form a device isolation region 180 by known shallow trench isolation (STI) techniques.

Thereafter, form pFinFET 150 in one semiconductor region 102. This pFinFET has a channel region on the Box layer 108, with its channel plane being identical to a {110} crystal plane. Thus the pFinFET 150 has SOI structure.

In the remaining semiconductor region 130, form nFinFET 160 to have its channel region which is formed on bulk-silicon. The channel direction of this nFinFET is in parallel with the channel direction of pFinFET 150 as shown in FIG. 1. Accordingly the nFinFET 160 has its channel plane on a {100} plane. The nFinFET 160's channel direction may alternatively be arranged to be normal to that of pFinFET 150, when the need arises.

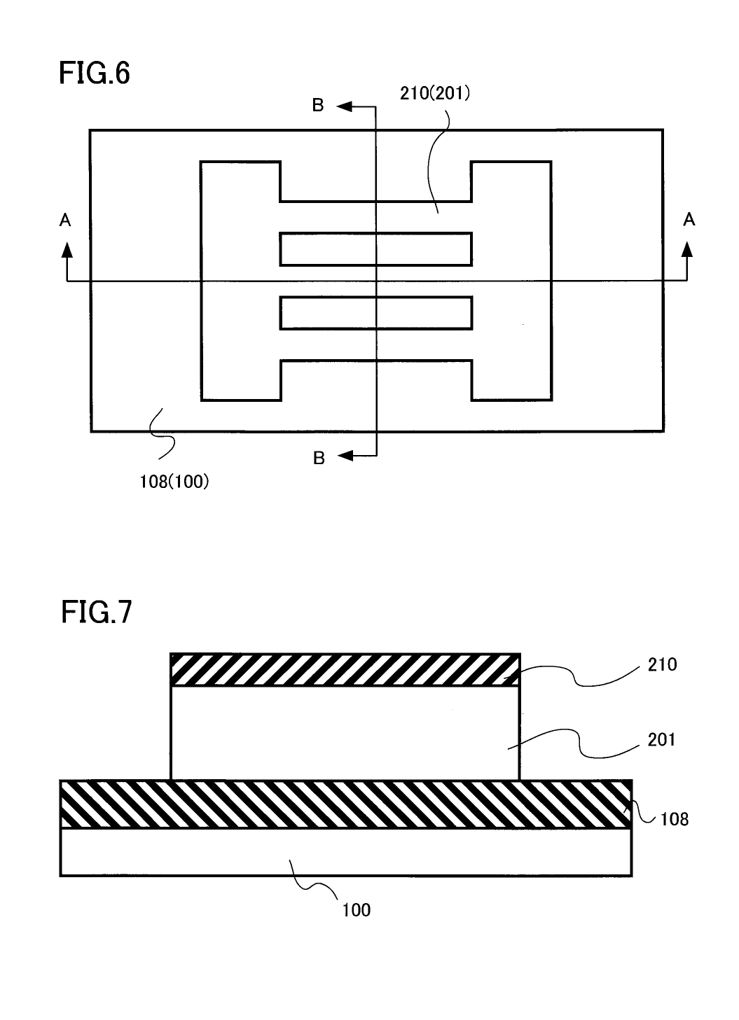

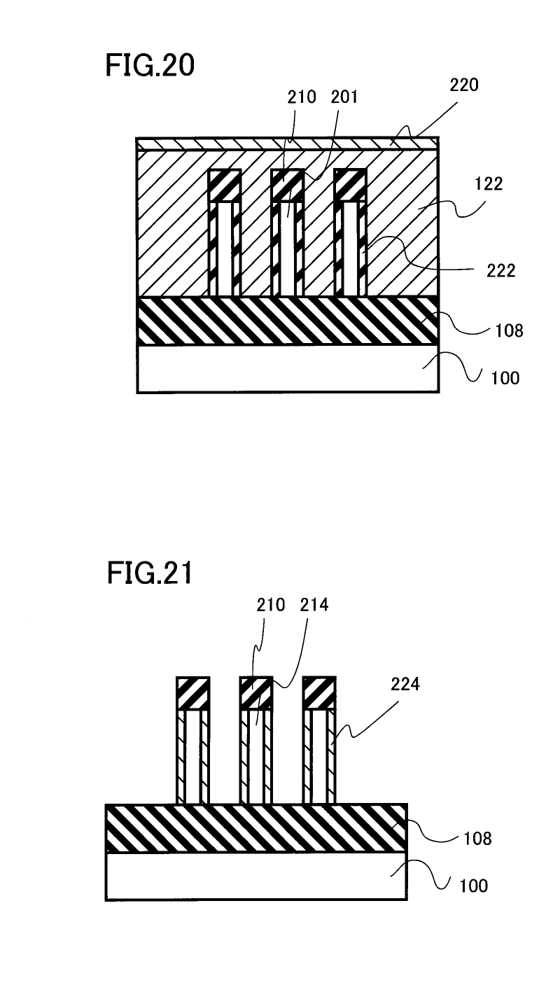

An exemplary fabrication process of the pFinFET 150 and nFinFET 160 will be explained with reference to FIGS. 6 through 21. The explanation below exemplifies the pFinFET 150 to be formed in one semiconductor region 120 of FIG. 1. A fabrication process of the remaining nFinFET 160 is similar in essence to that of pFinFET 150 except for the following: the Box layer 108 underlying the STI device isolation region is not formed; and, an impurity for formation of source/drain (S/D) regions—i.e., kind of dopant—is different.

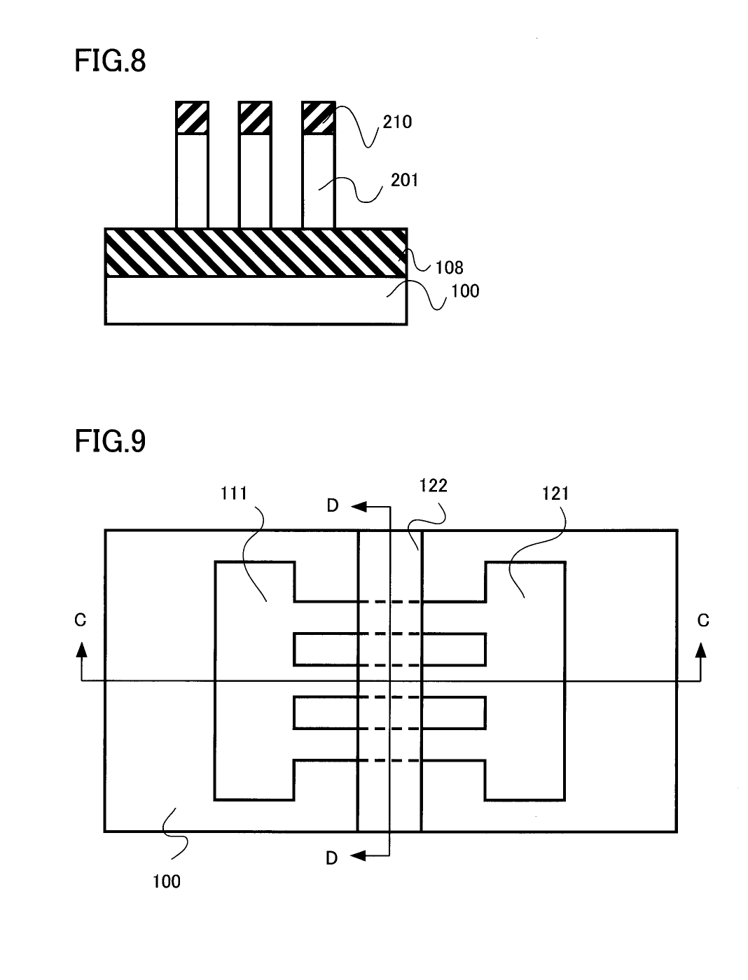

As shown in FIGS. 6-8, wherein FIG. 6 is a plan view diagram and FIGS. 7-8 show cross-sectional views, deposit by LPCVD a silicon nitride (SiN) film 201 with a thickness of about 50 to 100 nm on the SOI layer on Box layer 108 atop Si layer 100. This film is for use as a channel protector. Then, use known isolation techniques to form an device isolation region (not shown). Note here that FIG. 7 depicts a cross-section as taken along line A-A of FIG. 6 whereas FIG. 8 shows a cross-section taken along line B-B of FIG. 6.

Subsequently, etch the SiN film 210 and SOI layer by lithography and RIE etching to thereby form a structure 201 having three vertically standing fins between a pair of spaced-apart “wall” portions. Thus, its top plan shape resembles Roman numeral “III” as can be seen from FIG. 6. This fin structure 201 is for use as the device region of FinFET. Each fin has a width (horizontal layer thickness) of about 10 nm. When the need arises, dope a chosen impurity by oblique or “tilted” ion implantation techniques into the channel region. This is for threshold voltage adjustment.

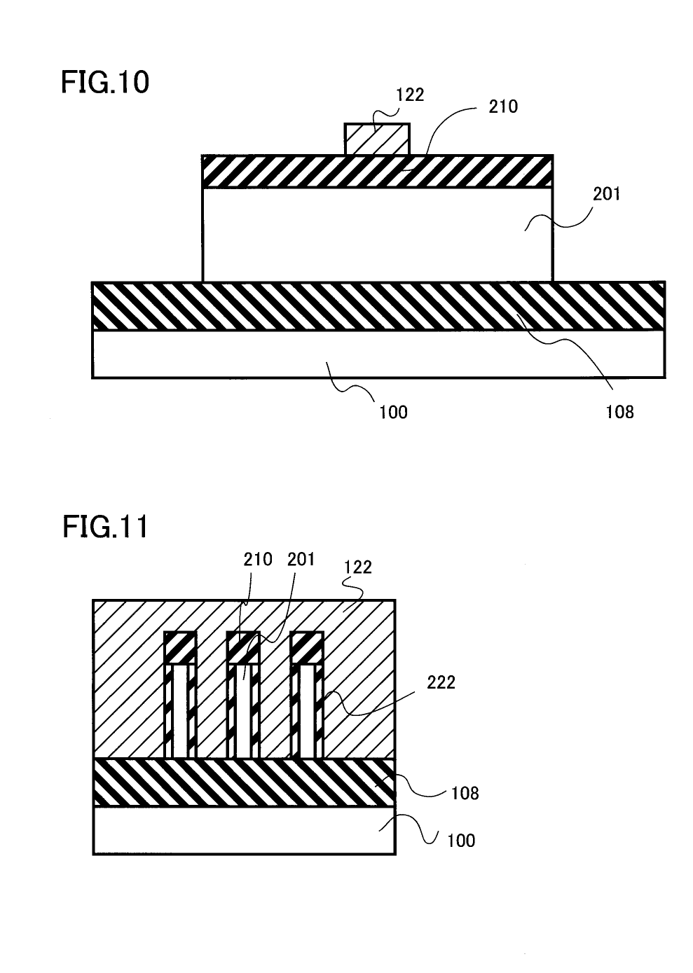

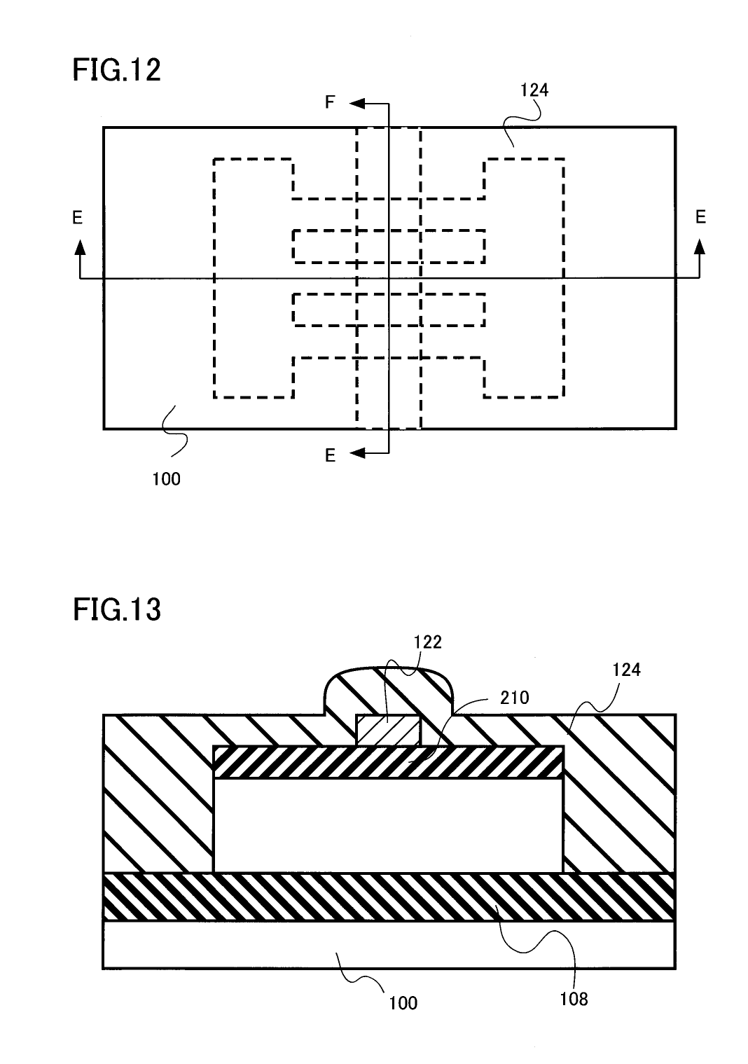

Next, as shown in FIGS. 9 to 11, form by rapid thermal oxidation (RTO) an SiOₓ film of about 1 nm in such a way as to cover central portions of vertical fin sidewalls (channel plane) of the fin structure 201. Note that FIG. 10 is a plan view of the resultant device structure at this step, FIG. 11 depicts a cross-section of it taken along line C-C, and FIG. 12 shows a cross-section along line D-D of FIG. 10. Next, apply plasma nitridation to the SiOₓ film to form a gate insulator film 222. This film is increased in dielectric constant owing to the plasma nitridation. Gate insulator 222 may alternatively be a high-dielectric-constant (high-k) dielectric film, which may be formed by chemical vapor deposition (CVD) or atomic layer deposition (ALD) methods.

Subsequently, on the gate insulator film 222, deposit a polycrystalline silicon (poly-Si) film by LPCVD to a thickness of about 100 nm. On this poly-Si film, deposit a SiN hard mask layer (not shown). Then, pattern this hard mask by lithography and RIE techniques. With the patterned hard mask layer as a mask, pattern the poly-Si film to thereby form a gate electrode 122. Thereafter, optionally, an off-set spacer may be formed.

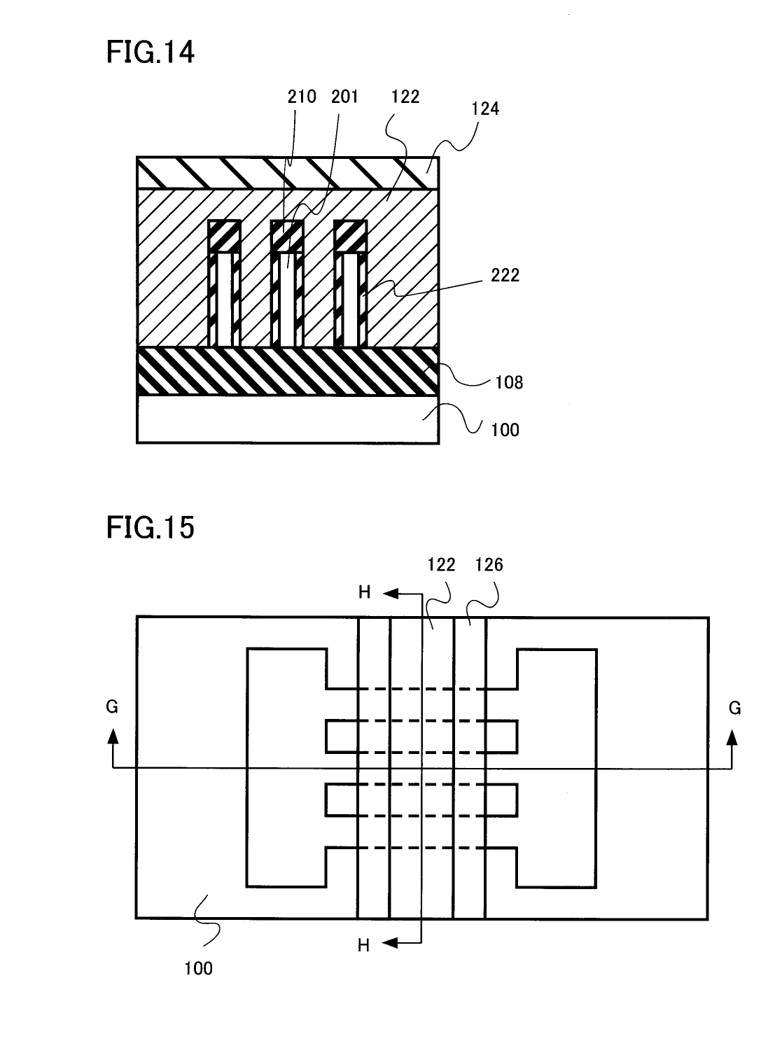

Next, as shown in FIGS. 12-14, deposit by LPCVD a SiN film 124 to a thickness of about 100 nm. FIG. 12 depicts a plan view of the device structure at this step, FIG. 13 shows a cross-section of it as taken along line E-E, and FIG. 14 is a cross-section along line F-F of FIG. 12.

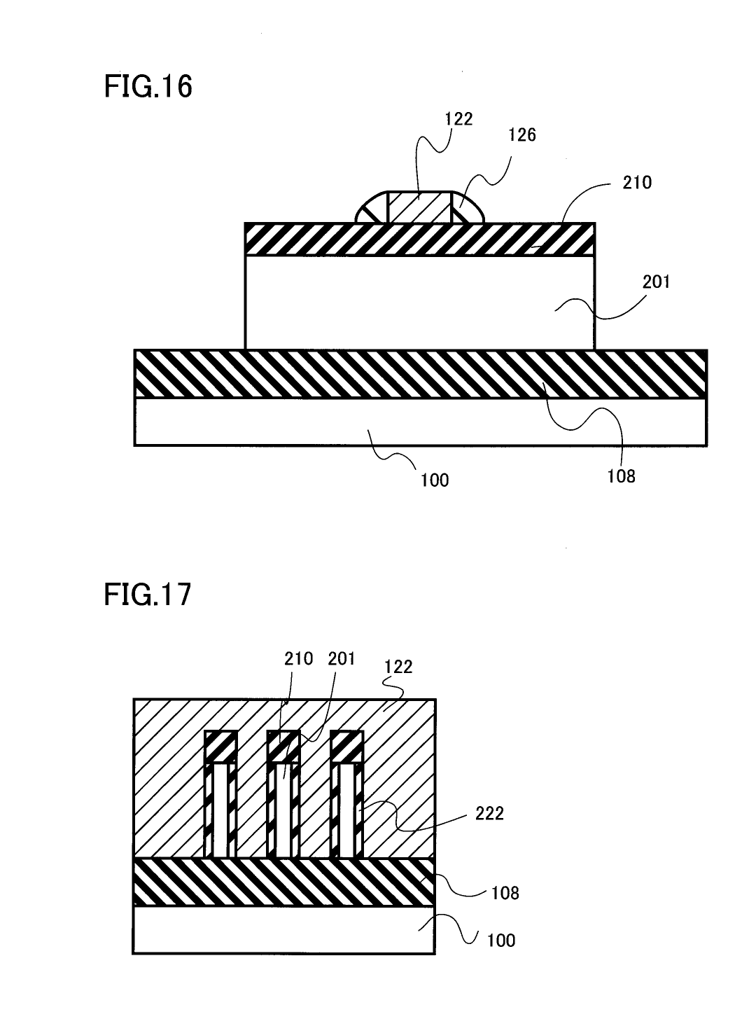

Next, as shown in FIGS. 15-17, selectively remove the SiN film 124 by lithography and RIE processes to thereby form gate sidewall insulators 126. FIG. 15 depicts a plan view of the device structure at this step, FIG. 16 shows a cross-section of it as taken along line G-G, and FIG. 17 is a cross-section along line H-H of FIG. 15.

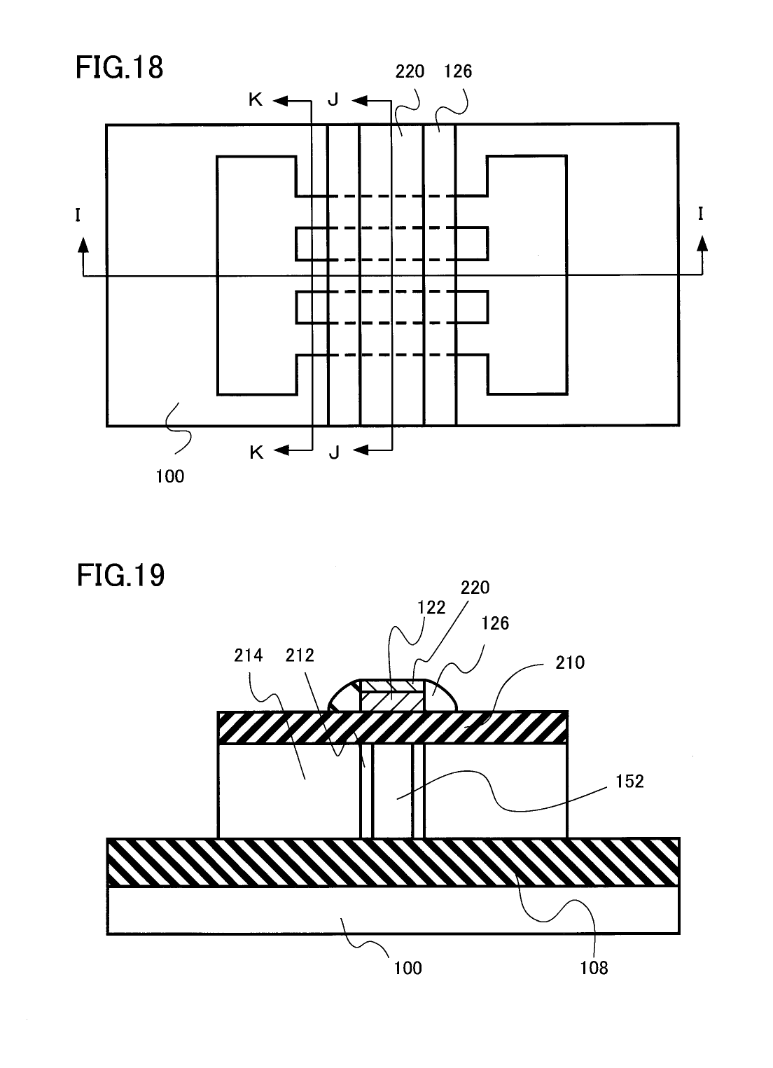

Next, as shown in FIGS. 18-21, perform ion implantation of a chosen p-type impurity, e.g., boron (B), with a dosage of about 1×10¹⁴ cm⁻² under application of an acceleration voltage of about 1 KeV, thereby forming an extension diffusion layer 212. Also perform ion implantation of an n-type impurity, e.g., arsenic (As), with a dosage of about 1×10¹⁵ cm⁻² under application of an acceleration voltage of about 30 KeV, thereby to form a deep diffusion layer 214. Fin 201 between these paired impurity-doped regions becomes a channel region 152 of pFinFET 150. FIG. 18 depicts a plan view of the device structure at this step, FIGS. 19-21 show cross-sections of it as taken along lines I-I, J-J and K-K, respectively. After completion of each ion implantation process, the resulting device structure may be subjected to activation annealing appropriately on a case-by-case basis. A “halo” implant region may be additionally provided in order to suppress short channel effects.

Next, form a pair of silicide layers 224 for use as source/drain (S/D) regions which are self-aligned with the gate, through sputtering of a high-melting-point metal, such as nickel (Ni), and thermal processing thereof. Simultaneously, form a gate silicide layer 220 on gate electrode 122. At this time the S/D region's deep diffusion layer 214 may be entirely silicidized. This silicidation leads to a decrease in parasitic resistance of FinFET and also to enhancement of transistor performance. Alternatively, the poly-Si layer of gate electrode 122 may be entirely silicided to thereby provide what is called the fully silicided (FUSI) structure. Use of this FUSI structure suppresses unwanted gate depletion and delay due to gate wiring resistance, which in turn leads to achievement of higher performances of a semiconductor device using FinFETs.

Through the process steps above, CMOS device which has pFinFET and nFinFET on the bonded SOI substrate is fabricated, wherein the channel planes of these FinFETs are disposed either in parallel with or at right angles to each other. The pFinFET has its channel plane with a {110} crystal orientation. As the pFinFET's channel direction is identical to a <110> direction, its hole mobility becomes higher. On the contrary, the nFinFET's channel plane has a crystal orientation of a {100} plane, so nFinFET is high in electron mobility.

With the above-stated fabrication method of fin-type CMOSFET device structure, it is possible to form, without having to place significant constraints on integrated circuit designs, the intended pair of pFinFET and nFinFET each having its maximized carrier mobility. Thus it is possible to achieve a highly integrated CMOS semiconductor device that is large in drive current and yet less in channel leakage current.

Although in this embodiment the bond wafer 102 and base wafer 104 of the bonded SOI substrate 110 are both made of silicon, similar results are obtainable when either one or both of the wafers may be made of silicon germanium, SiₓGe₁₋ₓ (0<x<1).

### Embodiment 2

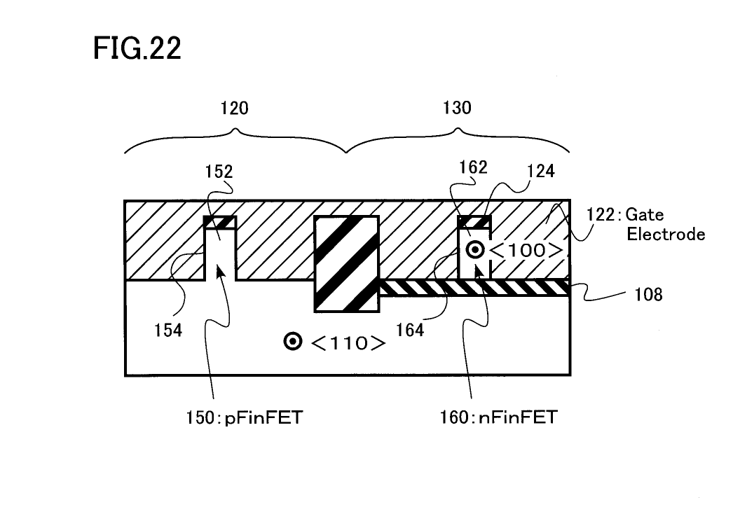

Referring to FIG. 22, a CMOSFET device with fin-type channel structure is illustrated in sectional diagram form, which device is formed by a fabrication method in accordance with another embodiment of the invention. This fin-type CMOS device is similar to that shown in FIG. 1 with a pair of FinFETs being modified so that pFinFET 150 is formed on a bulk-silicon region whereas nFinFET 160 is formed on SOI substrate.

More specifically, a semiconductor region 120 is formed on the substrate by selective epitaxial growth techniques. In this region, form pFinFET 150. Define an SOI layer overlying Box layer 108 as another semiconductor region 130, in which nFinFET 160 is formed.

In the device structure of FIG. 22, the nFinFET 160 has SOI structure so that its robustness against short channel effects is improved. Accordingly, use of this structure may be preferably employable in cases where device circuit designs require nFinFETs to have higher short-channel effect immunity than that of pFinFETs.

### Embodiment 3

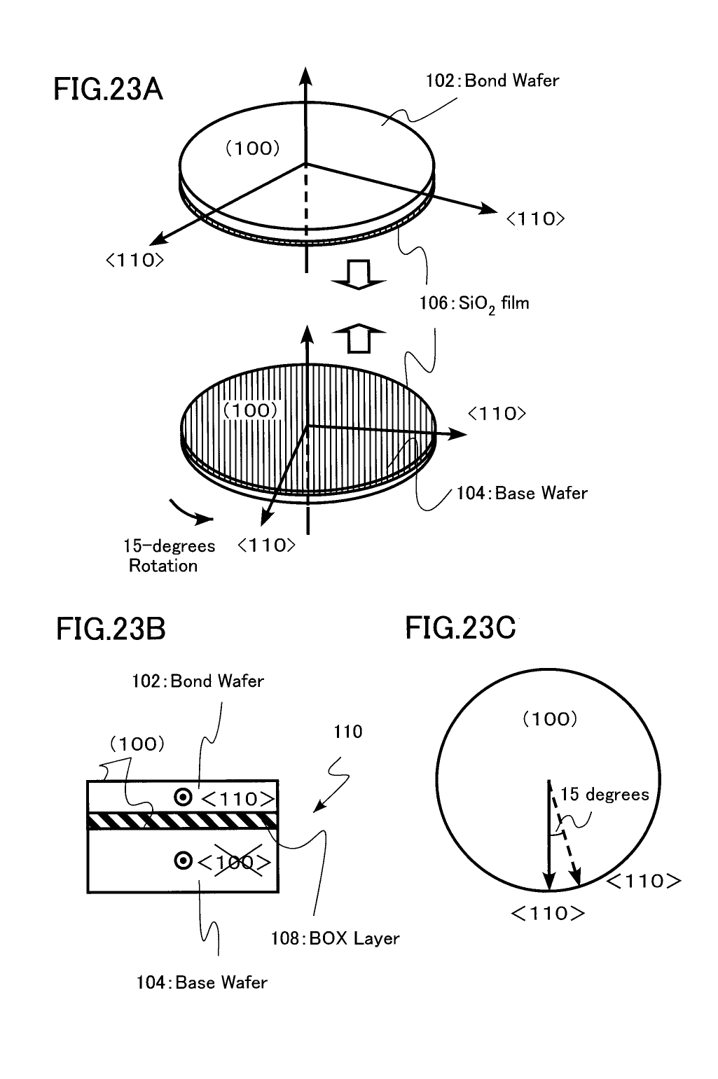

At the above-stated Si wafer bonding step shown in FIGS. 2A-2C, the SOI substrate 110 may be fabricated while setting the rotation angle between the <110> directions of bond wafer 102 and base wafer 104 to 15 degrees rather than 45 degrees. This is shown in FIGS. 23A-23C. These views correspond to FIGS. 2A-2C, respectively. Additionally in this example, the nFinFET formed on this substrate is arranged so that its channel plane does not have the {100} crystal orientation. The pFinFET is formed so that its channel plane has a {110} crystal plane. As better shown in FIG. 23B, a cross-section of Si base wafer 104 is prevented from being normal to the <100> direction in the cross-section perpendicular to the <110> direction of Si bond wafer 102 of SOI substrate 110.

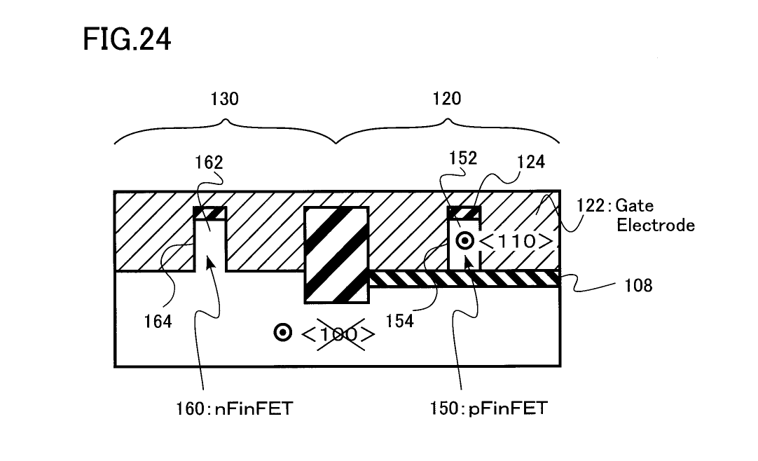

A fin-channel CMOSFET device formed on this bonded SOI substrate is shown in FIG. 24 in sectional diagram form. As shown herein, the pFinFET 150's channel direction is a <110> direction. Thus, its channel plane 154 has crystallographic orientation of a {110} plane. In contrast, the nFinFET 160's channel direction is not a <100> direction. Thus, its channel plane is a crystal plane that is slanted or tilted by 30 degrees with respect to the {100} plane.

According to this embodiment, as in the first embodiment stated previously, the pFinFET 150 has its channel direction of <110> and channel plane on the {110} plane that is the highest in hole mobility among major crystal planes of silicon. This pFinFET is laid out so that it is either in parallel with or normal to the nFinFET 160. This makes it possible to obtain higher LSI integration while at the same time maximizing the pFinFET 150 in performance.

It should be noted that the advantage of pFinFET 150 does not come without accompanying a penalty which follows: nFinFET 160 is little lowered in its transistor performance because of its channel plane being slanted or “sloped” by an angle of 30 degrees relative to the {100} plane. Nevertheless, nFinFET 160 offers higher electron mobility when compared to prior known FinFETs. Prior art fin-type CMOSFET devices are usually designed to have a Si wafer with its surface on a (100) crystal plane. On this wafer surface, a pFinFET is formed thereon to have its channel plane on a {110} plane, with an nFinFET being disposed in parallel to the pFinFET. Thus the nFinFET's channel plane is identical to the {110} plane. In contrast, the device structure of FIG. 24 is such that the nFinFET channel plane is angled by 30 degrees relative to the {100} plane, resulting in the electron mobility on this plane becoming greater than that obtained by the prior art parallel layout design.

Additionally the setup value of rotation angle of 15 degrees between the bond wafer 102 and base wafer 104 is illustrative only. Similar results are obtainable when such angle value is varied as far as it is kept more than zero in practical applications.

### Embodiment 4

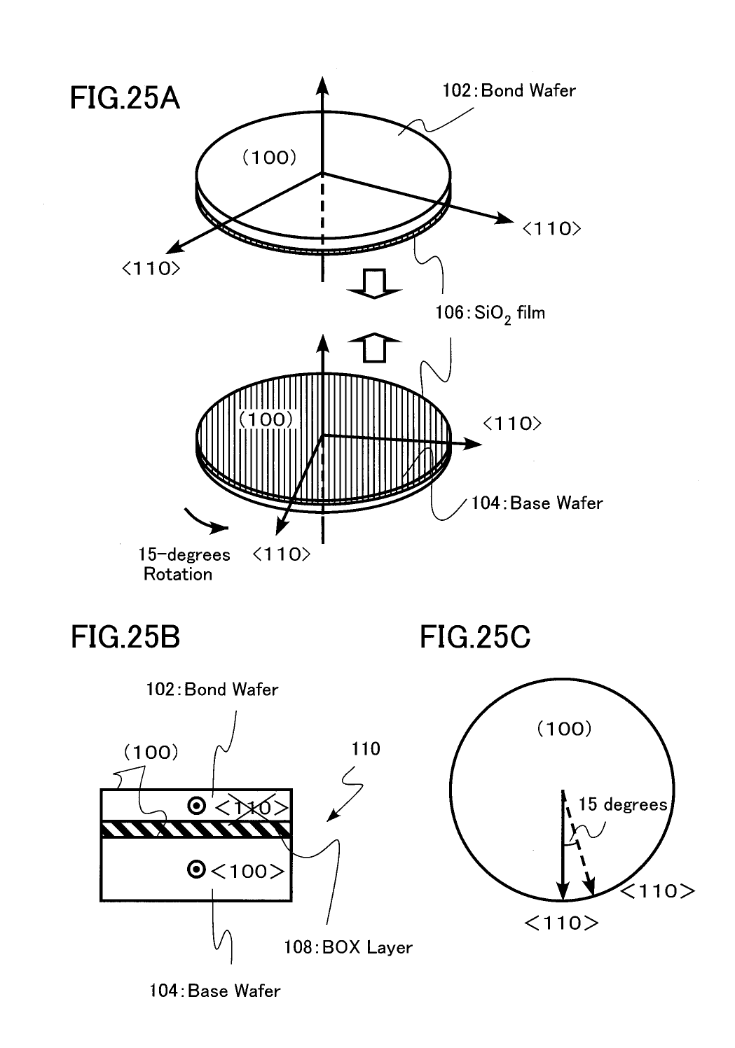

At the above-stated Si wafer bonding step shown in FIGS. 2A-2C, the SOI substrate 110 may be formed while setting the rotation angle between the <110> directions of bond wafer 102 and base wafer 104 to 15 degrees rather than 45 degrees. This is shown in FIGS. 25A-25C. These views correspond to FIGS. 2A-2C, respectively. Additionally in this example, the pFinFET formed on this substrate is arranged so that its channel plane does not have the {110} crystal orientation. The nFinFET is formed so that its channel plane has a {100} plane. As better shown in FIG. 25B, a cross-section of Si bond wafer 102 is prevented from being normal to the <110> direction in the cross-section perpendicular to the <100> direction of Si base wafer 104 of SOI substrate 110.

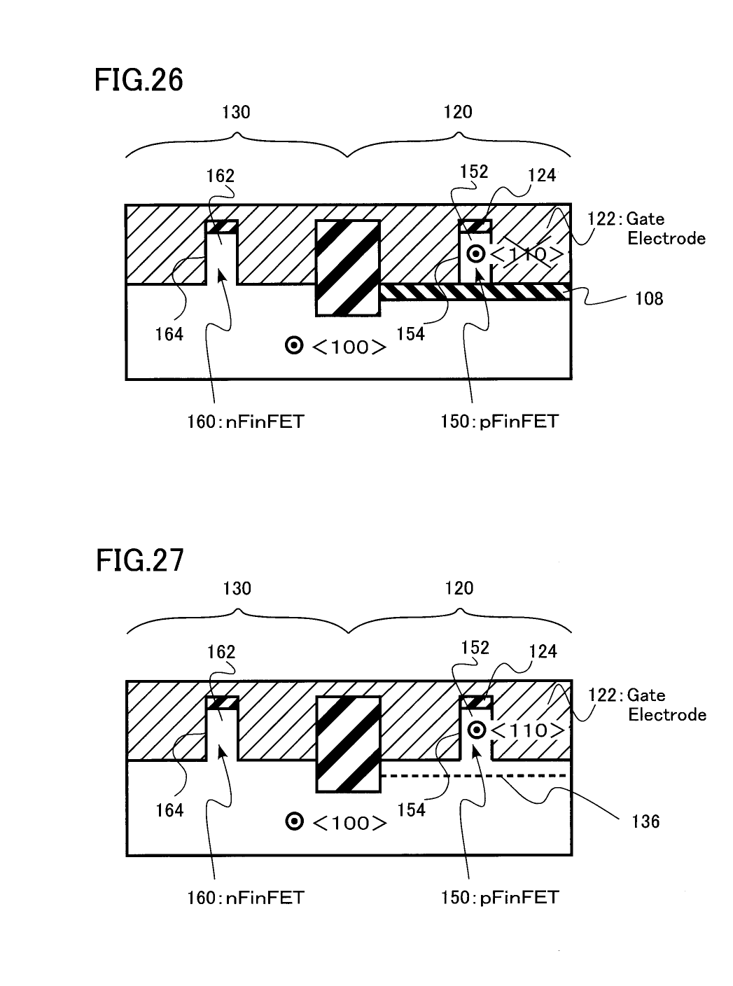

A fin-channel CMOSFET device formed on this bonded SOI substrate is shown in FIG. 26 in sectional diagram form. As shown herein, the nFinFET 160's channel direction is a <100> direction. Thus, its channel plane 164 has crystallographic orientation of a {100} plane. In contrast, the pFinFET 150's channel direction is not the <110> direction. Thus, its channel plane is a crystal plane that is tilted by 30 degrees with respect to the {110} plane.

According to this embodiment, as in the first embodiment stated supra, the nFinFET 160 has its channel plane on the {100} plane that is the highest in electron mobility among major crystal planes of Si. This nFinFET is laid out so that it is either in parallel with or normal to the pFinFET 150. This makes it possible to obtain higher LSI integration while at the same time maximizing the nFinFET 160 in performance.

It is noted that the advantage of nFinFET 160 does not come without accompanying a penalty which follows: pFinFET 150 is little lowered in its transistor performance because of its channel plane being slanted by an angle of 30 degrees relative to the {110} plane. Nevertheless, pFinFET 150 offers higher hole mobility when compared to prior known FinFETs. Prior art fin-type CMOSFET devices are usually designed to have a Si wafer with its surface on a (100) crystal plane. On this wafer surface, an nFinFET is formed thereon to have its channel plane on a {100} plane, with a pFinFET being disposed in parallel to the nFinFET. Thus the pFinFET's channel plane is identical to the {100} plane. On the contrary, the device structure of FIG. 26 is such that the pFinFET channel plane is angled by 30 degrees relative to the {110} plane, resulting in the hole mobility on this place becoming greater than that obtained by the prior art parallel layout design.

Additionally the setup value of rotation angle of 15 degrees between the bond wafer 102 and base wafer 104 is an example only. As in the third embodiment, similar results are obtainable if this angle value is made variable as far as it is kept more than zero in practical applications.

### Embodiment 5

A fin-channel CMOS device structure shown in FIG. 27 is similar to that shown in FIG. 1 with the bonded SOI substrate being replaced by what is called the direct silicon bonded (DSB) substrate. DSB substrate is the one that has two separate Si wafers directly bonded together in the absence of any thick SiOₓ film at the bonding interface thereof. Between these direct bonded wafers, no continuous SiOₓ film is formed. As apparent from viewing FIG. 27, this DSB substrate is such that crystal orientation-different Si layers are in contact with each other at an interface 136 with no SiOₓ film therebetween.

To make the DSB substrate of FIG. 27, process conditions are appropriately controlled when bonding two Si wafers—i.e., a bond wafer and a base wafer—to ensure that an SiOₓ film at bonding interface is 5 nm or less in thickness. After having thinned the bond wafer by polishing or else, thermal processing is performed in a hydrogen atmosphere at 1250° C. for about one hour, causing residual oxygen at the interface to outdiffuse to thereby remove any oxide film away from the interface. On the resultant DSB substrate, p/n-type FinFETs are fabricated in a way similar to that of the first embodiment stated supra.

To form crystal orientation-different semiconductor regions on a top surface of the DSB substrate, it is recommendable to use an amorphization/templated recrystallization (ATR) technique. This ATR process typically includes the steps of amorphizing the upper single-crystalline Si layer up to its bonding interface with the lower layer by ion implantation of Si rather than selective growth of Si, and performing recrystallization by annealing in such a way that the upper layer takes over or “inherits” the crystallographic orientation of the lower layer, thereby forming on the Si wafer top surface the intended silicon regions that are different in crystal orientation from each other.

According to this embodiment, both the pFinFET and nFinFET are formed on the bulk silicon (bulk-Si), it becomes possible to omit those processes relating to integrated circuit designs otherwise needed when using an SOI substrate. This results in an increase in flexibility of such circuit design. Thus it is possible to manufacture high-performance semiconductor devices at low costs.

### Embodiment 6

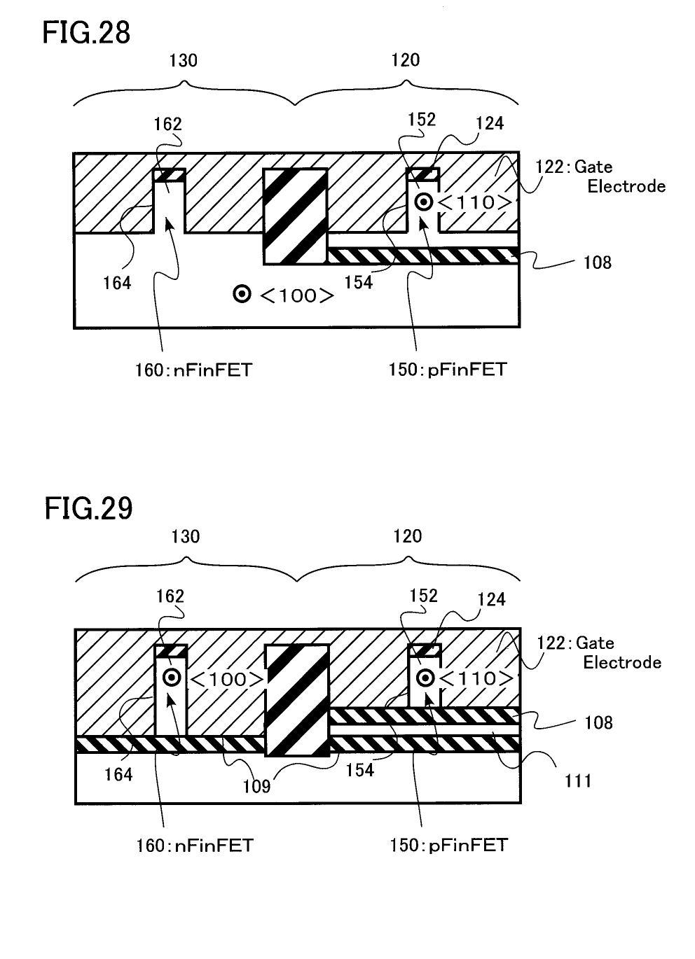

A fin-channel CMOS device structure also embodying the invention is shown in FIG. 28 in sectional diagram form. This device is similar to that shown in FIG. 1 with the pFinFET 150 being modified so that its fin height is lower than the thickness of SOI layer. More specifically, as shown in FIG. 28, the level of Box layer 108 in the pFinFET formation area of base wafer 104 is lower than the contact level of this wafer with bond wafer 102 in the nFinFET formation area, thus permitting interposition of a single-crystal Si layer atop Box layer 108, on which layer the fin channel region 152 is formed. This structure is equivalent to a device with pFinFET 150 formed on bulk-Si.

To make the device structure of FIG. 28, during formation of the SOI substrate, process conditions are adequately set to reduce the polish amount of Si bond wafer 102 and also to force the thickness of SOI layer to be greater than the fin height that was initially determined by device design. Alternatively, at the step of forming the pFinFET, process conditions are controlled so that the fin height is less than the thickness of SOI layer. According to this embodiment, the resulting device structure is equivalent to the case where the pFinFET and nFinFET are both formed on bulk-Si so that similar results are obtainable to those obtained by the device of FIG. 27.

### Embodiment 7

A cross-sectional structure of a fin-channel CMOS device structure also embodying the invention is shown in FIG. 29. This device is similar to that shown in FIG. 1 with the pFinFET 150 and nFinFET 160 being modified so that both of them have the SOI structure.

To fabricate this device structure, prior to surface-bonding of Si wafers for formation of an SOI substrate, a base wafer which is one of the wafers is prepared by bonding together two separate Si wafers—say, sub-base wafers—with a Box layer 109 sandwiched therebetween. After having thinned by CMP or else the bonded base wafer at its top surface, use a similar technique to that of the above-stated first embodiment to adhere a bond wafer to this base wafer, thereby forming the intended SOI substrate having a three-wafer lamination or “tri-Si-layer” structure. This substrate has two, upper and lower Box layers 108 and 109 as shown in FIG. 29.

Then, form by selective epitaxial growth a semiconductor region 130 which is used for formation of nFinFET 160 therein. At this step, etching is performed in a way such that it stops when reached to the upper Box layer 108, causing silicon to selectively grow while inheriting the crystal structure of a Si layer interposed between Box layers 108 and 109 (corresponding to the upper sub-base wafer). This Si layer between Box layers 108-109 may be about 10 nm in thickness.

As this embodiment device is formed so that both the pFinFET and nFinFET have the SOI structure, each offers increased durability against short channel effects. Thus the channel leakage current is further reduced, thereby enabling achievement of further improved transistor characteristics. In addition, when compared to CMOS devices with only pFinFET being designed to have the SOI structure, the embodiment device is appreciably improved in symmetry of CMOS circuitry. This reduces complexities in on-chip circuit designs.

### Embodiment 8

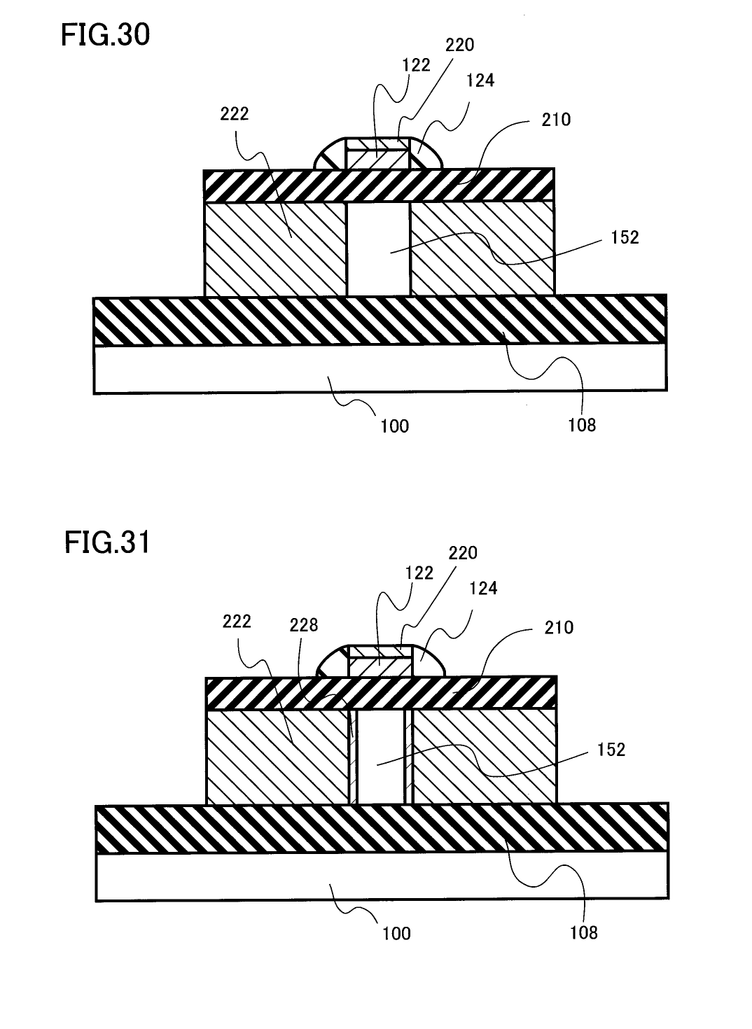

A method of fabricating a fin-channel CMOS device structure in accordance with a further embodiment of this invention is similar to the fabrication process of the fin CMOS device shown in FIG. 1 as has been discussed while referring to FIGS. 2-21, except that the pFinFET 150 and nFinFET 160 are formed so that each has a Schottky junction at its source/drain (S/D) regions. See FIG. 30, which shows a cross-sectional view of pFinFET thus formed by this embodiment method. This sectional view corresponds to that shown in FIG. 19.

As shown in FIG. 30, the S/D regions are each entirely formed of a layer of metal or metal silicide, e.g., nickel silicide (NiSi) layer 222. NiSi layer 222 and channel region 152 have therebetween a metal-semiconductor junction, i.e., Schottky junction. Although not specifically illustrated herein, the same goes with S/D regions of nFinFET.

In the manufacture of the device structure of FIG. 30, no extension diffusion and deep diffusion layers are formed at the step of forming pFinFET and nFinFET. Silicidizing S/D regions results in formation of Schottky junctions in these regions.

In this embodiment device the individual one of the pFinFET and nFinFET has the Schottky junction so that each FET becomes higher in durability against short channel effects. Thus, channel leakage currents are much suppressible, thereby making it possible to fabricate the semiconductor device with further improved transistor characteristics.

### Embodiment 9

A method of fabricating a fin-channel CMOS device structure also embodying the invention is similar to the process of making the fin CMOS device of FIG. 1 as has been discussed with reference to FIGS. 2-21 except that the pFinFET 150 and nFinFET 160 are formed so that each has a segregation Schottky junction at its source/drain (S/D) regions. See FIG. 31, which illustrates in cross-section a pFinFET thus formed by this embodiment method. This sectional view corresponds to that shown in FIG. 19.

As shown in FIG. 31, each S/D region is entirely formed of a layer of metal or metal silicide, e.g., NiSi layer 222. NiSi layer 222 and channel region 152 have, between metal and semiconductor, a junction having an ultra-thin heavily-doped impurity layer 228 that was formed through segregation of an impurity doped during silicidation, that is, dopant-segregated Schottky junction. Although not specifically depicted herein, the same goes with S/D regions of nFinFET.

In the manufacture of the FIG. 31 device structure, either extension diffusion layers or deep diffusion layers are formed at S/D regions at the step of forming pFinFET and nFinFET. Fully siliciding these diffusion layers results in the formation of impurity-segregated high-concentration impurity layers 228 at the interfaces between silicides and channel regions. In this way, the dopant-segregated Schottky junctions of S/D regions are formed.

According to this embodiment device, the individual one of the pFinFET and nFinFET has the Schottky junction so that each becomes higher in durability against short channel effects. In addition, owing to the presence of the dopant-segregated Schottky junction having the heavily-doped impurity layers 228, the junction interface decreases in electrical resistance. Thus, drive current can be increased keeping channel leakage currents still at low level, thereby enabling fabrication of the semiconductor device with further improved transistor characteristics.

### Embodiment 10

The above-stated fin-channel CMOS device fabrication method of the first embodiment is modifiable to further include the step of forming, after having formed the p/nFinFETs, planar MOSFETs of p- and/or n-channel type on the same Si substrate.

More specifically, after the formation of the pFinFET and nFinFET on Si substrate, or alternatively, during formation of part of them, form by known processes at least one P-channel type MOSFET (PMOSFET) of the planar type or at least one planar N-channel MOSFET (NMOSFET) or a combination thereof on the same Si substrate on which the FinFETs are formed or being presently formed. Another approach is to employ a process having the steps of forming, after having formed these planar transistors on Si substrate or alternatively during formation of portions thereof through known processes, the pFinFET 150 and nFinFET 160 of FIG. 1 on the same substrate by the fabrication method of the first embodiment.

This embodiment permits planar FETs—these are more excellent than FinFETs in large drive current and high voltage withstand characteristics—to be integrated together with FinFETs as on-chip circuit elements used for peripheral circuitry of hybrid ULSIs, by way of example. This in turn enables achievement of a semiconductor device capable of maximally satisfying respective different or “conflicting” circuit functionality/performance requirements at a time.

While the invention has been described with reference to specific embodiments, the description is illustrative of the invention and is not to be construed as limiting the invention. Various modifications and applications may occur to those skilled in the art without requiring any inventive activities. The invention is, therefore, to be limited only as indicated by the scope of the appended claims.

What is claimed is:

1. A method of fabricating a semiconductor device, comprising:
preparing a semiconductor substrate having a top surface formed by bonding together two separate first and second wafers so that <110> direction of the first wafer and <110> direction of the second wafer cross each other at a prespecified rotation angle, wherein the first wafer having {100} surface orientation and the second wafer having {100} surface orientation,;
forming two semiconductor regions on the top surface of the semiconductor substrate, the semiconductor regions including a first region having <110> direction substantially identical to <110> direction of the first wafer and a second region having <110> direction substantially equal to <110> direction of the second wafer;
forming in the first region a p-channel type fin field effect transistor (“pFinFET”) with a channel plane orientation thereof being substantially identical to {110} orientation; and
forming in the second region an n-channel type fin field effect transistor (“nFinFET”) with its channel direction being in parallel with or normal to a channel direction of the pFinFET.

2. The method according to claim 1, wherein at least one of the first and second wafers is made of silicon germanium given as SiₓGe₁₋ₓ, where x is a positive number less than or equal to one (0<x≦1).

3. The method according to claim 1, wherein the rotation angle is set to approximately forty five (45) degrees with an allowable error range of plus/minus two (±2) degrees.

4. The method according to claim 1, wherein the semiconductor substrate is a silicon-on-insulator (SOI) substrate.

5. The method according to claim 4, wherein each of the pFinFET and the nFinFET is formed to have an SOI structure.

6. The method according to claim 1, wherein the semiconductor substrate is formed by directly bonding together the first and second wafers.

7. The method according to claim 1, wherein the forming of the pFinFET is forming the pFinFET to have source and drain regions with Schottky junctions and wherein the forming of the nFinFET is forming the nFinFET to have source and drain regions with Schottky junctions.

8. The method according to claim 7, wherein the each Schottky junction is a dopant-segragated Schottky junction.

9. The method according to claim 1, further comprising:
forming in any one of the first and second regions a planar transistor.

10. A method of fabricating a semiconductor device, comprising:
preparing a semiconductor substrate having a top surface formed by bonding together two separate first and second wafers so that <110> direction of the first wafer and <110> direction of the second wafer cross each other at a prespecified rotation angle, wherein the first wafer having {100} surface orientation and the second wafer having {100} surface orientation,;
forming two semiconductor regions on the top surface of the semiconductor substrate, the semiconductor regions including a first region having <110> direction substantially identical to <110> direction of the first wafer and a second region having <110> direction substantially equal to <110> direction of the second wafer;
forming in the first region a n-channel type fin field effect transistor (“nFinFET”) with a channel plane orientation thereof being substantially identical to {100} orientation; and
forming in the second region an p-channel type fin field effect transistor (“pFinFET”) with its channel direction being in parallel with or normal to a channel direction of the nFinFET.

11. The method according to claim 10, wherein at least one of the first and second wafers is made of SiₓGe₁₋ₓ (0<x≦1)

12. The method according to claim 10, wherein the semiconductor substrate is an SOI substrate.

13. The method according to claim 12, wherein each of the pFinFET and the nFinFET is formed to have an SOI structure.

14. The method according to claim 10, wherein the semiconductor substrate is formed by directly bonding together the first and second wafers.

15. The method according to claim 10, wherein the forming of the pFinFET is forming the pFinFET to have source and drain regions with Schottky junctions and wherein the forming of the nFinFET is forming the nFinFET to have source and drain regions with Schottky junctions.

16. The method according to claim 15, wherein the each Schottky junction is a dopant-segregated Schottky junction.

17. The method according to claim 10, further comprising:
forming in any one of the first and second regions a planar transistor.
